(19) United States
(12) Patent Application Publication
(10) Pub. No.: US 2016/0178706 A1
(43) Pub. Date: Jun. 23, 2016

(54) METHOD AND APPARATUS OF DETECTING STATES OF BATTERY

(71) Applicant: NATIONAL CHUNG SHAN INSTITUTE OF SCIENCE AND TECHNOLOGY, Longtan Township (TW)

(72) Inventors: CHIH-PENG LIU, LONGTAN TOWNSHIP (TW); WEI-MIN HSIAO, LONGTAN TOWNSHIP (TW); FU-MIN FANG, LONGTAN TOWNSHIP (TW); KUO-KUANG JEN, LONGTAN TOWNSHIP (TW); MING-LIANG HUANG, LONGTAN TOWNSHIP (TW); SHU-HSIEN WEN, LONGTAN TOWNSHIP (TW)

(21) Appl. No.: 14/573,232

(22) Filed: Dec. 17, 2014

(51) Int. Cl. G01R 31/36

(52) U.S. Cl. CPC G01R 31/3679; G01R 31/3651; G01R 31/3675

(57) ABSTRACT

A method and apparatus of detecting the states of a battery involve passing test-oriented charging and discharging pulse pair to a battery under test, and retrieving parameters of the battery, such as voltage, current, and temperature, which respond to the charging and discharging pulse pair, so as to estimate the battery states. The battery states include information pertaining to open-circuit voltage, internal resistance, capacitance, state of charge, and state of health of the battery. The battery state-related information is conducive to quick battery state detection and grading.

### FIELD OF TECHNOLOGY

The present invention relates to battery state detection technology, and more particularly, to a method and apparatus of detecting the states of a battery, which apply to second-use applications of batteries retired from motor-driven carriers.

### BACKGROUND

With fossil fuels dwindling and power battery technology developing, human beings attach increasingly great importance to issues, such as energy saving, carbon reduction, green energy sources, and environmental protection, with a view to protecting the environment of the Earth and coping with the climate changes of the Earth. Motor-driven carriers like electric motorcycles and electric buses are emerging under the auspices of governments around the world. It is predicted that the electric vehicle market will become sophisticated and widespread in years to come.

A power battery is intended to power a motor-driven carrier, but it ages with cumulative working hours and mileage. Causes and signs of battery aging abound. Among them, two major indicators are the reduction of battery capacity and the increase of battery internal resistance.

Related studies show that when the battery capacity of a power battery for use with a motor-driven carrier decreases to less than 70˜80% of its nominal delivery capacity, it is appropriate to decide that the power battery no longer meets the power requirement of the motor-driven carrier. Hence, motor-driven carrier manufacturers need a method of detecting the states of a battery to assess the aging stage and present performance of the battery and thus provide reference for deciding the best retirement time, grading, and selection. Effective battery grading and recombination is conducive to application of retired batteries to an energy storage system, so as to extend their service life, enhance their efficiency, and cut their selling prices.

US20070252600, entitled diagnosis method for state-of-health of batteries, discloses diagnosing a state of health (SOH) of a battery, wherein the battery is discharged with a constant current for a long period of time, such that the voltage of the battery and the voltage variation rate of the battery are measured to assess the health status of the battery. But it takes several hours detecting the health status of the battery and thus fails to meet the need for quick real-time diagnosis of battery health status.

US20090128097, entitled method and system for tracking battery state of health, discloses calculating the capacitance accumulated in a battery according to the charging and charging time of the battery and then performing a comparison and analysis process on the calculated capacitance and the predefined capacitance of the battery so as to determine the health status of the battery. But the method takes time performing detection and thus fails to effectuate quick state detection.

U.S. Pat. No. 6,281,683, entitled rapid determination of present and potential battery capacity, discloses measuring the voltage of a battery during the period when the battery passes a pulse current and the open-circuit voltage (OCV) of the battery during the period when the battery is idle according to a plurality of discharging pulses and a plurality of idle periods, calculating the voltage difference between the pulses, and calculating the residual capacity and maximum charging capacity of the battery with a table or a mathematical equation. Although the method is effective in calculating the capacity of a battery quickly, the method gives no consideration to the state of a battery under test and idle periods. As a result, the method fails to measure the open-circuit voltage of a battery accurately and thus causes estimation errors.

European patent 06075610.3, entitled method and device for determining characteristics of an unknown battery, discloses a method of evaluating a battery capacity, by measuring the voltage of a battery during the second period when the battery passes the pulse current and the open-circuit voltage (OCV) of the battery during the second idle period with at least two discharging pulses, calculating the voltage difference between the pulses, estimating the charging and discharging rate (C rate) of the battery in accordance with the voltage difference and by means of a table of a mathematical equation, and calculating the capacity of the battery in accordance with the charging and discharging rate of the battery. Although the method is effective in calculating the capacity of a battery quickly, the idle periods are so short that the method fails to measure the open-circuit voltage of a battery accurately and thus causes estimation errors.

Japan published patent application 2007-178333 discloses allowing a battery to idle for a while and then measuring the voltage variation rate of the battery as the charging current of the battery changes from a constant current to a constant voltage while the battery is charging, so as to assess the aging stage of the battery. But the method not only requires interrupting the charging behavior of a battery but is also restricted to a point in time of changing the charging current from a constant current to a constant voltage; as a result, the method has narrow applicability.

Taiwan patent application 098127249, entitled method of estimating lithium-ion battery capacity by direct current internal resistance, discloses building an additional discharging loop in a battery module, regulating battery load discharge with the discharging loop to maintain a constant total discharging current of the battery, measuring the internal resistance of the battery, and estimating the battery capacity with a table by making reference to the predefined relationship between the internal resistance and the capacity of the battery. But the method gives considerations to only the battery state of battery discharging. Furthermore, the battery state is unknown before each instance of discharge, thereby leading to uncertainty of the discharging voltage measured. Moreover, since the actual battery open-circuit voltage cannot be measured in a short period of time, errors in the calculated internal resistance of a battery are quite common.

As indicated above, all conventional methods and apparatuses of detecting the states of a battery have the aforesaid limits and drawbacks in application, including: (1) although a complete battery charging and discharging process is effective in estimating the battery capacity, detection takes so long that it is impossible to detect the battery state quickly; (2) the evaluation of the battery capacity by means of discharging pulses requires the open-circuit voltage of the battery, but electrical chemical reactions usually take several hours; as a result, the actual open-circuit voltage cannot be figured out quickly, thereby leading to evaluation errors; (3) given a specific testing requirement, for example, the point in time of changing the charging current from a constant current to a constant voltage, the states of a battery can be detected only in a specific battery state, thereby leading to a limit in application; and (4) most testing methods can only evaluate a specific battery parameter, such as battery capacity or internal resistance, thereby failing to explore the states of a battery comprehensively.

### SUMMARY

In view of the aforesaid drawbacks of the prior art, it is an objective of the present invention to provide a method and apparatus of detecting the states of a battery, which involve passing test-oriented charging and discharging pulse pair to the battery under test, retrieving parameters of the battery, such as voltage, current, and temperature, which respond to the charging and discharging pulse pair, so as to estimate the battery states. The states of the battery include information pertaining to open-circuit voltage, internal resistance, capacitance, state of charge (SOC), and state of health (SOH) of the battery. The battery state-related information is conducive to quick battery state detection and grading.

In order to achieve the above and other objectives, the present invention provides a method of detecting the states of a battery, comprising the steps of: setting control parameters of a charging and discharging pulse pair test, wherein the control parameters include charging pulse current, discharging pulse current, charging pulse time width, discharging pulse time width, open-circuit time width, and the number of charging and discharging pulse pairs; performing a charging and discharging pulse pair test on the battery; measuring pulse response parameters of the battery, wherein the pulse response parameters include maximum voltage of charging pulse, minimum voltage of discharging pulse, OCV of charging pulse, OCV of discharging pulse, and temperature; calculating average voltage parameters, wherein the average voltage parameters include average maximum voltage of charging pulse, average minimum voltage of discharging pulse, and average OCV; calculating average voltage differences between charging pulses and discharging pulses and state of charge (SOC); calculating charging and discharging internal resistance; calculating charging and discharging internal resistance-related SOH indexes; calculating actual charging and discharging battery capacitance, charging the battery fully when the battery is brand-new, performing a discharging and charging test in a constant current-constant voltage mode to create a charging and discharging database of the battery, followed by substituting measured average voltage differences between charging pulses and discharging pulses and a state of charge (SOC) into the database to figure out actual charging battery capacity and actual discharging battery capacity of the battery; calculating charging and discharging capacity-related SOH indexes; and figuring out an overall battery health status index, wherein the overall battery health status index equals the least one of the charging internal resistance-related SOH index, discharging internal resistance-related SOH index, charging capacity-related SOH index, and discharging capacity-related SOH index.

In an embodiment, the charging pulse current, the discharging pulse current, the charging pulse time width, and the discharging pulse time width satisfy a relation as follows: I_{C}×t_{C}−I_{D}×t_{D}=0, wherein I_{C} denotes the charging pulse current, I_{D} denotes the discharging pulse current, t_{C} denotes the charging pulse time width, and t_{D} denotes the discharging pulse time width.

In an embodiment, the average maximum voltage of charging pulse, the average minimum voltage of discharging pulse, and the average OCV are calculated with the following equations:

$$\overline{{V}_{OC}} = \frac{1}{( {I}_{C} + {I}_{D} ) \times ( N - M + 1 )} {\sum }_{i = M}^{N} ( {V}_{OCi} \times {I}_{C} + {V}_{ODi} \times {I}_{D} )$$

$$\overline{{V}_{C}} = \frac{1}{N - M + 1} {\sum }_{i = M}^{N} {V}_{Ci}$$

$$\overline{{V}_{D}} = \frac{1}{N - M + 1} {\sum }_{i = M}^{N} {V}_{Di}$$

wherein V̅_̅{̅C̅}̅ denotes the average maximum voltage of charging pulse, V̅_̅{̅D̅}̅ denotes the average minimum voltage of discharging pulse, V̅_̅{̅O̅C̅}̅ denotes the average OCV, V_{Ci} denotes the maximum voltage of the i^{th} charging pulse, V_{Di} denotes the minimum voltage of the i^{th} discharging pulse, V_{OCi} denotes the OCV of the i^{th} charging pulse, V_{ODi} denotes the OCV of the i^{th} discharging pulse, T denotes the temperature, wherein both M and N are positive integers, and M is less than N.

In an embodiment, an average voltage difference of the charging pulses and an average voltage difference of the discharging pulses are calculated with the following equations: Δ̅V̅_̅{̅C̅}̅=V̅_̅{̅C̅}̅−V̅_̅{̅O̅C̅}̅ and Δ̅V̅_̅{̅D̅}̅=V̅_̅{̅O̅C̅}̅−V̅_̅{̅D̅}̅,̅ wherein Δ̅V̅_̅{̅C̅}̅ denotes the average voltage difference of the charging pulses, and Δ̅V̅_̅{̅D̅}̅ denotes the average voltage difference of the discharging pulses.

In an embodiment, the charging internal resistance-related SOH index and the discharging internal resistance-related SOH index are calculated with the following equations:

$${SOH}_{RC} = \frac{γ \times {R}_{NEW} - {R}_{C}}{( γ - 1 ) \times {R}_{NEW}} \times 100 \%$$

$${SOH}_{RD} = \frac{γ \times {R}_{NEW} - {R}_{D}}{( γ - 1 ) \times {R}_{NEW}} \times 100 \%$$

wherein SOH_{RC} denotes the charging internal resistance-related SOH index, SOH_{RD} denotes the discharging internal resistance-related SOH index, R_{C} denotes the charging internal resistance, R_{D} denotes the discharging internal resistance, R_{NEW} denotes the brand-new battery internal resistance, γ denotes the number of times the battery internal resistance increases when the battery is recycled, wherein γ ranges from 1 to 3.

In an embodiment, the charging capacity-related SOH index and the discharging capacity-related SOH index are calculated with the following equations: SOH_{AHC}=(AHC_{C}−μ×AHC_{NEW})/(AHC_{NEW}−μ×AHC_{NEW})×100% and SOH_{AHD}=(AHC_{D}−μ×AHC_{NEW})/(AHC_{NEW}−×AHC_{NEW})×100%, wherein SOH_{AHC} denotes the charging capacity related SOH index, SOH_{AHD} denotes the discharging capacity-related SOH index, AHC_{C} denotes the actual charging capacity, AHC_{D} denotes the actual discharging capacity, AHC_{NEW} denotes the nominal capacity, and μ denotes the battery recycling multiple, wherein μ ranges from 0 to 1.

In order to achieve the above and other objectives, the present invention provides an apparatus of detecting the states of a battery, which comprises a pulse testing module, a measuring module, and a battery state evaluating module. The pulse testing module is electrically connected to the battery. The pulse testing module has a battery charging/discharging control unit, a battery charging unit, and a battery discharging unit. The pulse testing module generates charging and discharging pulse pairs to the battery, so as to perform a charging and discharging pulse test on the battery. The measuring module is electrically connected to the battery. The measuring module measures pulse response parameters of the battery. The battery state evaluating module is electrically connected to the pulse testing module and the measuring module. The battery state evaluating module provides the control parameters of the charging and discharging pulse pair to the pulse testing module, receives the pulse response parameters of the measuring module measured, and calculates performance indicators of the battery.

In an embodiment, the pulse response parameters include maximum voltage of charging pulses, minimum voltage of discharging pulses, OCV of charging pulses, OCV of discharging pulses, and temperature.

In an embodiment, the performance indicators include average open-circuit voltage, average voltage differences of charging pulses and discharging pulses, charging and discharging internal resistance, capacitance, state of charge, state of health, and/or overall battery health status.

In an embodiment, the apparatus of detecting the states of a battery operates by following the steps of: the battery state evaluating module sets control parameters of the charging/discharging pulse pair test and sends the control parameters to a battery charging/discharging control unit of the pulse testing module; the battery charging/discharging control unit controls the battery charging/discharging unit to generate charging pulse pair and discharging pulse pair, respectively, according to the control parameters, and send the charging pulse pair and the discharging pulse pair to the battery, so as to perform the charging and discharging pulse test; the measuring module measures pulse response parameters of the battery and sends the pulse response parameters to the battery state evaluating module; and the battery state evaluating module calculates performance indicators of the battery according to the pulse response parameters.

The aforesaid overview and the following description and drawings explain the ways, measures, and effects of achieving the intended objects of the present invention. The other objectives and advantages of the present invention are explained in the following description and drawings.

### BRIEF DESCRIPTION

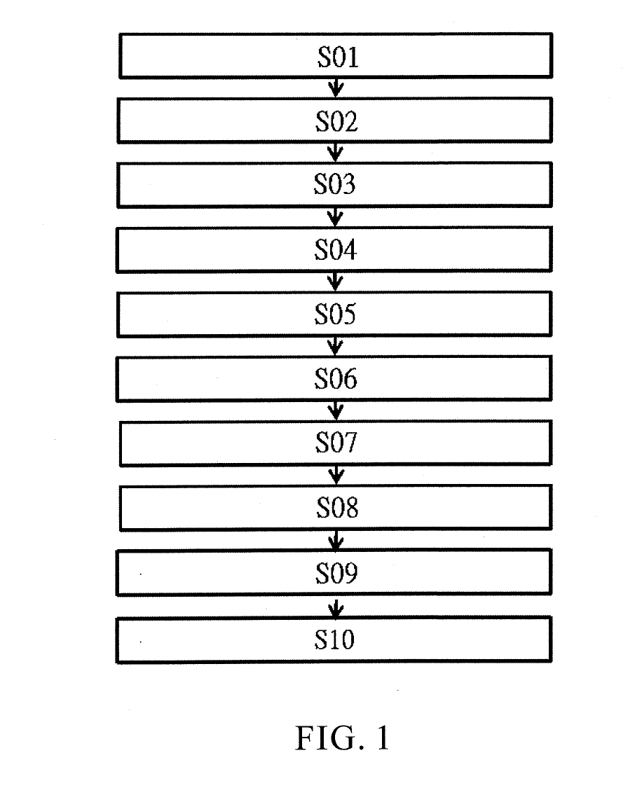

FIG. 1 is a flow chart of a method of detecting the states of a battery according to the present invention;

FIG. 2 is a waveform diagram of the charging and discharging pulse pairs and pulse response parameters according to the present invention;

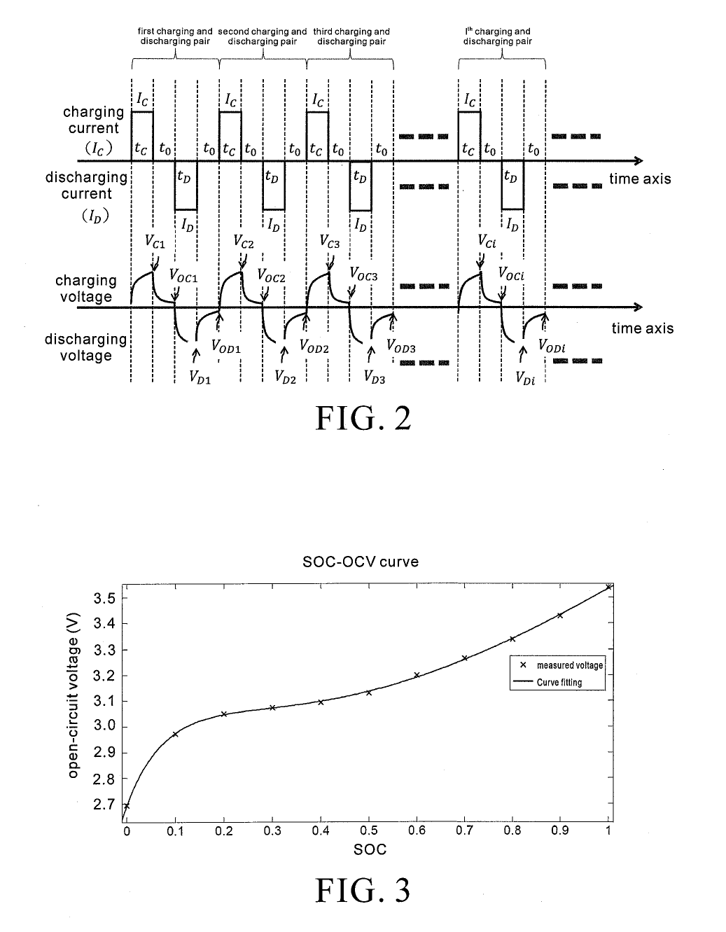

FIG. 3 is a graph of predefined battery state of charge (SOC) according to the present invention; and

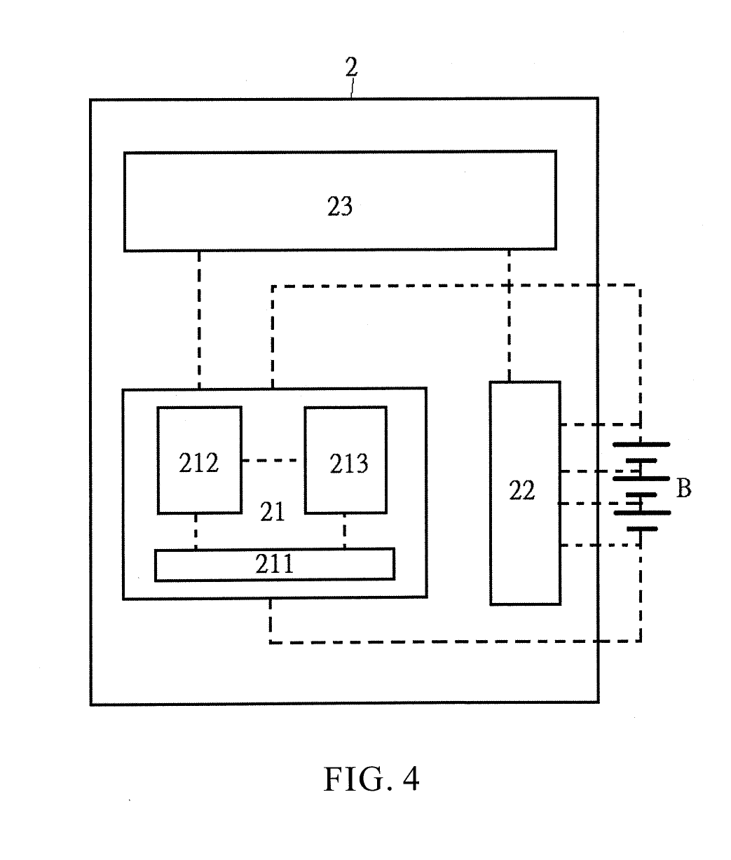

FIG. 4 is a function block diagram of apparatus of detecting the states of a battery according to the present invention.

### DETAILED DESCRIPTION

The implementation of the present invention is hereunder illustrated with specific embodiments. Persons skilled in the art can easily understand the other advantages and effects of the present invention by referring to the disclosure contained in this specification.

FIG. 1 is a flow chart of a method of detecting the states of a battery according to the present invention. As shown in the diagram, according to the present invention, the method of detecting the states of a battery is applicable to figuring out an overall battery health status index. The method comprises the steps below.

Step S01: setting control parameters of a charging/discharging pulse pair test, wherein the control parameters include charging pulse current (I_{C}), discharging pulse current (I_{D}), charging pulse time width (t_{C}), discharging pulse time width (t_{D}), open-circuit time width (t₀), and the number N of charging and discharging pulse pairs, to provide the charging and discharging pulse waveform required for performing the test on the battery, and generate N charging and discharging pulse pairs to perform battery state detection and analysis of the battery; wherein the charging pulse current (I_{C}) and the discharging pulse current (I_{D}) range from 0.2C to 1C, where C denotes battery charging and discharging rate (C rate) and are defined as the quotients of dividing the charging and discharging current by the capacity (in ampere-hour) of the battery; the time width of detection control timing (t_{C}, t_{D}, t₀) ranges from 3 seconds to 30 seconds; N ranges from 1 to 10; to ensure that the accumulated capacitance always equals the released capacitance, the charging pulse current (I_{C}), the discharging pulse current (I_{D}), the charging pulse time width (t_{C}), and the discharging pulse time width (t_{D}) must satisfy a relation as follows:

I_{C}×t_{C}−I_{D}×t_{D}=0

Step S02: performing a charging and discharging pulse pair test on the battery, wherein the test is performed by passing N charging and discharging pulse pairs to the battery according to predefined charging pulse current (I_{C}), discharging pulse current (I_{D}), charging pulse time width (t_{C}), discharging pulse time width (t_{D}), open-circuit time width (t₀), and the number N of charging and discharging pulse pairs.

Step S03: measuring pulse response parameters of the battery, wherein the pulse response parameters include maximum voltage of charging pulse (V_{Ci}), minimum voltage of discharging pulse (V_{Di}), the OCV of charging pulse (V_{OCi}), OCV of discharging pulse (V_{ODi}), and temperature T, wherein i denotes the i^{th} charging and discharging pulse pair, wherein the maximum voltage of charging pulse (V_{Ci}), the minimum voltage of discharging pulse (V_{Di}), the OCV of charging pulse (V_{OCi}), and the OCV of discharging pulse (V_{ODi}) are figured out by measuring the i^{th} charging and discharging pulse pair, wherein the pulse waveform of the charging and discharging pulse pair and the waveform of the pulse response parameters are shown in FIG. 2.

Step S04: calculating average voltage parameters; to enhance the precision of battery state evaluation and preclude evaluation deviation caused by an unknown track record of the battery, it is feasible to reduce errors and variations of measured parameters by the averaging concept of statistical theories; by making reference to the voltage measured during the charging and discharging pulse pair test, step SO4 entails calculating average voltage parameters which include average maximum voltage of charging pulse (V̅_̅{̅C̅}̅), average minimum voltage of discharging pulse (V̅_̅{̅D̅}̅), and average OCV (V̅_̅{̅O̅C̅}̅) with the following equations:

$$\overline{{V}_{OC}} = \frac{1}{( {I}_{C} + {I}_{D} ) \times ( N - M + 1 )} {\sum }_{i = M}^{N} ( {V}_{OCi} \times {I}_{C} + {V}_{ODi} \times {I}_{D} )$$

$$\overline{{V}_{C}} = \frac{1}{N - M + 1} {\sum }_{i = M}^{N} {V}_{Ci}$$

$$\overline{{V}_{D}} = \frac{1}{N - M + 1} {\sum }_{i = M}^{N} {V}_{Di}$$

where M, N denote positive integers, with M indicating the M^{th} charging and discharging pulse pair, wherein M is 1, 2, or any appropriate integer, but M must be less than N; hence, the aforesaid equations express the average measured voltage of the M^{th} charging and discharging pulse pair through the N^{th} charging and discharging pulse pair; the average measured voltage of the charging and discharging pulse pairs is calculated from the M^{th} charging and discharging pulse pair, because the pre-test states of the battery are unknown, and thus it is feasible to discard measures of the preceding charging and discharging pulse pairs as needed with a view to enhancing the precision of battery state detection.

Step S05: calculating average voltage differences of charging pulses and discharging pulses and a state of charge (SOC); to explore the responses of the battery to the pulse pair, it is necessary to calculate the average voltage differences of charging pulses and discharging pulses, wherein the average voltage differences of charging pulses is Δ̅V̅_̅{̅C̅}̅=V̅_̅{̅C̅}̅−V̅_̅{̅O̅C̅}̅, and the average voltage differences of discharging pulses is Δ̅V̅_̅{̅D̅}̅=V̅_̅{̅O̅C̅}̅−V̅_̅{̅D̅}̅; the state of charge (SOC) is calculated by substituting the average OCV (V̅_̅{̅O̅C̅}̅) into a predefined battery state of charge (SOC) graph (shown in FIG. 3); alternatively, or the corresponding state of charge (SOC) value is calculated by making reference to a related table.

Step S06: calculating charging and discharging internal resistance, charging internal resistance R_{C}=Δ̅V̅_̅{̅C̅}̅/I_{C}, and discharging internal resistance R_{D}=Δ̅V̅_̅{̅D̅}̅/I_{D}.

Step S07: calculating charging and discharging internal resistance-related SOH index, charging internal resistance-related SOH index SOH_{RC}, and discharging internal resistance-related SOH index SOH_{RD} with the following equation:

$${SOH}_{RC} = \frac{γ \times {R}_{NEW} - {R}_{C}}{( γ - 1 ) \times {R}_{NEW}} \times 100 \%$$

$${SOH}_{RD} = \frac{γ \times {R}_{NEW} - {R}_{D}}{( γ - 1 ) \times {R}_{NEW}} \times 100 \%$$

where γ expresses the number of times the internal resistance multiplies when the battery is recycled, i.e., the ratio (R_{END}/R_{NEW}=γ) of used battery internal resistance to new battery internal resistance, wherein γ ranges from 1 to 3, wherein, depending on the application scenario and the battery type, the γ of a lithium-ion battery preferably equals 1.2˜1.4 when the lithium-ion battery is intended for use with electric vehicles and preferably equals 2.5˜3 when the lithium-ion battery is intended for use with an energy storage system.

Step S08: calculating actual charging and discharging capacity, charging the battery fully when the battery is brand-new, performing a discharging and charging test in a constant current-constant voltage mode to create a charging and discharging database of the battery, and substituting the measured average voltage differences of charging pulses and discharging pulses (Δ̅V̅_̅{̅C̅}̅ and Δ̅V̅_̅{̅D̅}̅) and state of charge (SOC) into the charging and discharging database to figure out actual charging capacity AHC_{C}=ƒ(SOC, T, Δ̅V̅_̅{̅C̅}̅) and actual discharging capacity AHC_{D}=g(SOC, T, Δ̅V̅_̅{̅D̅}̅) of the battery, wherein f, g denote a predefined charging capacity function and a predefined discharging capacity function, respectively.

Step S09: calculating charging and discharging battery capacity-related SOH index, charging capacity-related SOH index SOH_{AHC}, and discharging capacity-related SOH SOH_{AHD} with the following equations:

SOH_{AHC}=(AHC_{C}−μ×AHC_{NEW})/(AHC_{NEW}−μ×AHC_{NEW})×100%

SOH_{AHD}=(AHC_{D}−μ×AHC_{NEW})/(AHC_{NEW}−μ×AHC_{NEW})×100%

where AHC_{NEW} denotes the nominal capacity of the battery; in practice, if the battery capacity is less than a specific capacity, it will be practicable to determine that the battery is no longer usable; for example, if the capacity of a lithium-ion battery is less than 40% of the capacity of a new battery, the lithium-ion battery must be immediately recycled and retired; hence, the present invention involves defining a battery recycling multiple μ, such that the battery must be immediately recycled when its capacity equals μ times the capacity of a new battery, wherein μ ranges from 0 to 1; the defined value of μ can be changed according to an application and a battery type; for example, μ preferably equals 0.7˜0.8 when the battery is intended for use with electric vehicles and μ preferably equals 0.4˜0.5 when the battery is intended for use with an energy storage system.

Step S10: figuring out an overall battery health status index, wherein the overall state of health (SOH) of the battery equals the least one of the charging internal resistance-related SOH index SOH_{RC}, discharging internal resistance-related SOH index SOH_{RD}, charging capacity-related SOH index SOH_{AHC}, and discharging capacity-related SOH index SOH_{AHD}, i.e.:

SOH=min(SOH_{RC},SOH_{AHC},SOH_{RD},SOH_{AHD})

FIG. 4 is a function block diagram of apparatus of detecting the states of a battery according to the present invention. As shown in the diagram, the apparatus 2 of detecting the states of a battery detects state parameters and performance indicators of a battery B. The apparatus 2 of detecting the states of a battery comprises a pulse testing module 21, a measuring module 22, and a battery state evaluating module 23. The pulse testing module 21 is electrically connected to the battery B. The pulse testing module 21 has a battery charging and discharging control unit 211, a battery charging unit 212, and a battery discharging unit 213. The pulse testing module 21 generates charging and discharging pulse pair and sends the charging and discharging pulse pair to the battery B, so as to perform a charging and discharging pulse test on the battery B. The measuring module 22 is electrically connected to the battery B. The measuring module 22 measures pulse response parameters of the battery B. The pulse response parameters include maximum voltage of charging pulse, minimum voltage of discharging pulse, OCV of charging pulse, OCV of discharging pulse, and temperature. The battery state evaluating module 23 is electrically connected to the pulse testing module 21 and the measuring module 22. The battery state evaluating module 23 provides control parameters of the charging/discharging pulse pair to the pulse testing module 21, receives pulse response parameters of the measuring module 22, and calculates performance indicators of the battery B. The performance indicators include open-circuit voltage, average voltage differences of charging and discharging pulse, charging and discharging internal resistance, capacitance, state of charge, state of health, and/or overall battery health status.

According to the present invention, the apparatus of detecting the states of a battery operates by following the steps: (a) the battery state evaluating module 23 sets control parameters of the charging/discharging pulse pair test and sends the control parameters to the battery charging/discharging control unit 211 of the pulse testing module 21; (b) the battery charging/discharging control unit 211 makes reference to the control parameters in controlling the battery charging unit 212 and the battery discharging unit 213 to generate charging pulse pair and discharging pulse pair, respectively, and send the charging pulse pair and the discharging pulse pair to the battery B, so as to perform a charging and discharging pulse pair test; (c) the measuring module 22 measures pulse response parameters of the battery B and sends the pulse response parameters to the battery state evaluating module 23; (d) the battery state evaluating module 23 calculates performance indicators of the battery B in accordance with the pulse response parameters.

The aforesaid embodiments are illustrative of the features and effects of the present invention only, but should not be interpreted as restrictive of the scope of the present invention. Hence, modifications and variations made by persons skilled in the art to the aforesaid embodiments without departing from the spirit and scope of the present invention should fall within the scope of the present invention. Accordingly, the legal protection for the present invention should be defined by the appended claims.

What is claimed is:

1. A method of detecting states of a battery, comprising the steps of:
setting control parameters of a charging and discharging pulse pair test, wherein the control parameters include charging pulse current, discharging pulse current, charging pulse time width, discharging pulse time width, open-circuit time width, and the number of charging and discharging pulse pairs;
performing a charging and discharging pulse pair test on the battery;
measuring pulse response parameters of the battery, wherein the pulse response parameters include maximum voltage of charging pulse, minimum voltage of discharging pulse, OCV of charging pulse, OCV of discharging pulse, and temperature;
calculating average voltage parameters, wherein the average voltage parameters include average maximum voltage of charging pulse, average minimum voltage of discharging pulse, and average OCV;
calculating average voltage differences of charging pulses and discharging pulses and state of charge (SOC);
calculating charging and discharging internal resistance;
calculating a charging internal resistance-related SOH index and a discharging internal resistance-related SOH index;
calculating actual charging and discharging capacity, charging the battery fully when the battery is brand-new, performing a discharging and charging test in a constant current-constant voltage mode to create a charging and discharging database of the battery, followed by substituting measured average voltage differences of charging pulses and discharging pulses and a state of charge (SOC) into the charging and discharging database to figure out actual charging capacity and actual discharging capacity of the battery;
calculating a charging capacity-related SOH index and a discharging capacity-related SOH index; and
figuring out an overall battery health status index, wherein the overall battery health status index equals the least one of the charging internal resistance-related SOH index, discharging internal resistance-related SOH index, charging capacity-related SOH index, and discharging capacity-related SOH index.

2. The method of claim 1, wherein the charging pulse current, the discharging pulse current, the charging pulse time width, and the discharging pulse time width must satisfy a relation as follows:
I_{C}×t_{C}−I_{D}×t_{D}=0
wherein I_{C} denotes the charging pulse current, I_{D} denotes the discharging pulse current, t_{C} denotes the charging pulse time width, and t_{D} denotes the discharging pulse time width.

3. The method of claim 2, wherein the average maximum voltage of charging pulse, the average minimum voltage of discharging pulse, and the average OCV are calculated with the following equations:
$$\overline{{V}_{OC}} = \frac{1}{( {I}_{C} + {I}_{D} ) \times ( N - M + 1 )} {\sum }_{i = M}^{N} ( {V}_{OCi} \times {I}_{C} + {V}_{ODi} \times {I}_{D} )$$
$$\overline{{V}_{C}} = \frac{1}{N - M + 1} {\sum }_{i = M}^{N} {V}_{Ci}$$
$$\overline{{V}_{D}} = \frac{1}{N - M + 1} {\sum }_{i = M}^{N} {V}_{Di}$$
wherein V̅_̅{̅C̅}̅ denotes the average maximum voltage of charging pulse, V̅_̅{̅D̅}̅ denotes the average minimum voltage of discharging pulse, V̅_̅{̅O̅C̅}̅, denotes the average OCV, V_{Ci} denotes the maximum voltage of charging pulse, V_{Di} denotes the minimum voltage of discharging pulse, V_{OCi} denotes the OCV of charging pulse, V_{ODi} denotes the OCV of discharging pulse, T denotes the temperature, wherein both M and N are positive integers, and M is less than N.

4. The method of claim 3, wherein the average voltage difference of the charging pulses and the average voltage difference of the discharging pulses are calculated with the following equations:
Δ̅V̅_̅{̅C̅}̅=V̅_̅{̅C̅}̅−V̅_̅{̅O̅C̅}̅
Δ̅V̅_̅{̅D̅}̅=V̅_̅{̅O̅C̅}̅−V̅_̅{̅D̅}̅
wherein Δ̅V̅_̅{̅C̅}̅ denotes the average voltage difference of the charging pulses, and Δ̅V̅_̅{̅D̅}̅ denotes the average voltage difference of the discharging pulses.

5. The method of claim 4, wherein the charging internal resistance-related SOH index and the discharging internal resistance-related SOH index are calculated with the following equations:
$${SOH}_{RC} = \frac{γ \times {R}_{NEW} - {R}_{C}}{( γ - 1 ) \times {R}_{NEW}} \times 100 \%$$
$${SOH}_{RD} = \frac{γ \times {R}_{NEW} - {R}_{D}}{( γ - 1 ) \times {R}_{NEW}} \times 100 \%$$
wherein SOH_{RC} denotes the charging internal resistance-related SOH index, SOH_{RD} denotes the discharging internal resistance-related SOH index, R_{C} denotes the charging internal resistance, R_{D} denotes the discharging internal resistance, R_{NEW} denotes the brand-new battery internal resistance, γ denotes the number of times the battery internal resistance multiplies when the battery is recycled, wherein γ ranges from 1 to 3.

6. The method of claim 5, wherein the charging capacity-related SOH index and the discharging capacity-related SOH index are calculated with the following equations:
SOH_{AHC}=(AHC_{C}−μ×AHC_{NEW})/(AHC_{NEW}−μ×AHC_{NEW})×100%
SOH_{AHD}=(AHC_{D}−μ×AHC_{NEW})/(AHC_{NEW}−μ×AHC_{NEW})×100%
wherein SOH_{AHC} denotes the charging capacity-related SOH index, SOH_{AHD} denotes the discharging capacity-related SOH index, AHC_{C} denotes the actual charging capacity, AHC_{D} denotes the actual discharging capacity, AHC_{NEW} denotes the nominal capacity, and μ denotes the battery recycling multiple, wherein μ ranges from 0 to 1.

7. An apparatus of detecting states of a battery, comprising:
a pulse testing module electrically connected to a battery, having a battery charging/discharging control unit, a battery charging unit, and a battery discharging unit, and adapted to generate charging and discharging pulse pair and provide the charging and discharging pulse pair to the battery, so as to perform a charging and discharging pulse test on the battery;
a measuring module electrically connected to the battery and adapted to measure pulse response parameters of the battery; and
a battery state evaluating module electrically connected to the pulse testing module and the measuring module and adapted to provide control parameters of the charging and discharging pulse pair to the pulse testing module and receive pulse response parameters of the measuring module measured so as to calculate performance indicators of the battery.

8. The apparatus of claim 7, wherein the pulse response parameters include maximum voltage of charging pulse, minimum voltage of discharging pulse, OCV of charging pulse, OCV of discharging pulse, and temperature.

9. The apparatus of claim 7, wherein the performance indicators include at least one of open-circuit voltage, average voltage difference of charging and discharging pulse, charging and discharging internal resistance, capacitance, state of charge, state of health, and/or overall battery health status index.

10. The apparatus of claim 7, wherein the apparatus operates by following the steps of:
the battery state evaluating module sets control parameters of the charging and discharging pulse pair test and sends the control parameters to the battery charging and discharging control unit of the pulse testing module;
the battery charging and discharging control unit makes reference to the control parameters in controlling the battery charging unit and the battery discharging unit to generate charging pulse pair and discharging pulse pair and send the charging pulse pair and discharging pulse pair to the battery, so as to perform the charging and discharging pulse pair test;
the measuring module measures pulse response parameters of the battery and sends the pulse response parameters to the battery state evaluating module; and
the battery state evaluating module calculates performance indicators of the battery in accordance with the pulse response parameters.
